(19) United States
(12) Patent Application Publication
(10) Pub. No.: US 2026/0040914 A1
(43) Pub. Date: Feb. 5, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Teng-Chuan Hu, Tainan City (TW); Chu-Fu Lin, Kaohsiung City (TW); Chuan-Lan Lin, Chiayi City (TW); Chun-Hung Chen, Tainan City (TW); Chiao-Hui Tu, Tainan City (TW)

(73) Assignee: UNITED MICROELECTRONICS CORP., Hsin-Chu City (TW)

(21) Appl. No.: 19/023,333

(22) Filed: Jan. 16, 2025

(30) Foreign Application Priority Data
Aug. 1, 2024 (TW) 113128639

(51) Int. Cl. H01L 23/48; H01L 21/768; H01L 23/00; H01L 25/07

(52) U.S. Cl. CPC H01L 23/481; H01L 21/76831; H01L 21/76832; H01L 24/80; H01L 25/074; H01L 24/08; H01L 2224/08145; H01L 2224/80895; H01L 2224/80896; H01L 2225/06541

(57) ABSTRACT

A method for fabricating semiconductor device includes the steps of first providing a stack structure having a shallow trench isolation (STI) under a first substrate, a contact etch stop layer (CESL) under the STI, an interlayer dielectric (ILD) layer under the CESL, and a first metal interconnection under the ILD layer and then forming a second metal interconnection penetrating through the first substrate, the STI, the CESL, and the ILD layer to contact the first metal interconnection and a liner adjacent to a sidewall of the second metal interconnection.

### BACKGROUND OF THE INVENTION

### 1. Field of the Invention

The invention relates to a method for fabricating semiconductor device, and more particularly, to a method of bonding two wafers and then forming a through-silicon via (TSV) on a backside of the top wafer.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (POP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating semiconductor device includes the steps of first providing a stack structure having a shallow trench isolation (STI) under a first substrate, a contact etch stop layer (CESL) under the STI, an interlayer dielectric (ILD) layer under the CESL, and a first metal interconnection under the ILD layer and then forming a second metal interconnection penetrating through the first substrate, the STI, the CESL, and the ILD layer to contact the first metal interconnection and a liner adjacent to a sidewall of the second metal interconnection.

According to another aspect of the present invention, a semiconductor device includes a shallow trench isolation (STI) under a first substrate, a contact etch stop layer (CESL) under the STI, an interlayer dielectric (ILD) layer under the CESL, a first metal interconnection under the ILD layer, a second metal interconnection penetrating through the first substrate, the STI, the CESL, and the ILD layer to contact the first metal interconnection, and a liner adjacent to a sidewall of the second metal interconnection.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-10 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

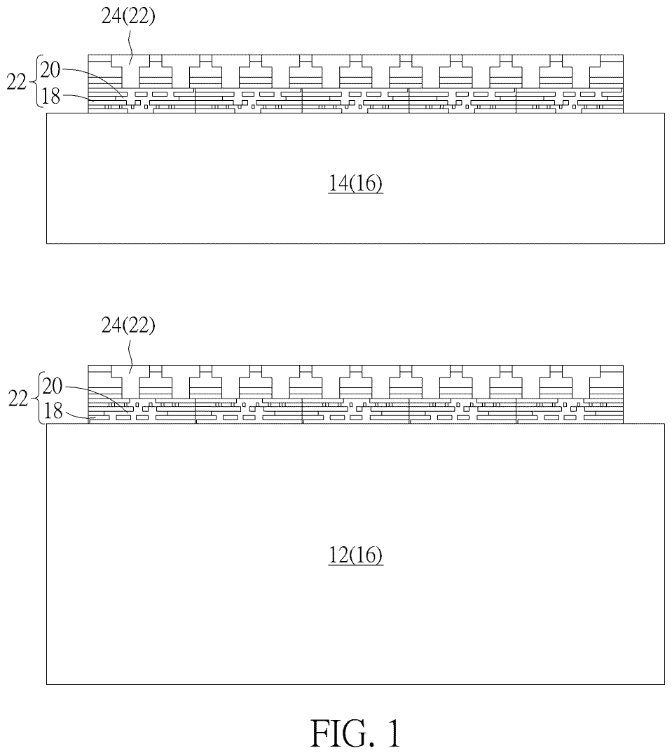

Referring to FIGS. 1-10, FIGS. 1-10 illustrate a method for fabricating a semiconductor device according to an embodiment of the present invention. As shown in FIG. 1, a bottom wafer 12 and a top wafer 14 both made of semiconductor material are provided. Preferably, each of the bottom wafer 12 and top wafer 14 includes a substrate 16 made of semiconductor materials, the substrates 16 could have same or different thicknesses depending on the fabrication or demand of the product, and each of the substrates 16 could also be made of semiconductor substrate material including but not limited to for example silicon substrate, epitaxial silicon substrate, silicon carbide substrate or even a silicon-on-insulator (SOI) substrate, which are all within the scope of the present invention. In this embodiment, each of the wafers 12, 14 could be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the bottom wafer 12 and top wafer 14 respectively. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers and metal interconnections on the aforementioned active devices and/or passive devices.

If a MOS transistor were to be fabricated, the FEOL process could include the steps of forming a gate structure on the substrate 16, forming a spacer (not shown) adjacent to sidewalls of the gate structure and a source/drain region in the substrate 16 adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 16 to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer 18 disposed on the ILD layer, and metal interconnections 20 in the IMD layer 18 for connecting the contact plugs, in which the IMD layer 18 and the metal interconnections 20 could constitute a metal interconnect structures 22 altogether and the topmost metal interconnection on front side of each of the wafers 12, 14 could be used as connecting junctions such as direct bond interconnects (DBIs) 24 as the two wafers could be bonded through DBIs 24 in the later process. In this embodiment, the ILD layer and the IMD layer 18 could include oxides including but not limited to for example tetraethyl orthosilicate (TEOS) and the contact plugs, the metal interconnections 20, and the DBIs 24 could include Al, Cr, Cu, Ta, Mo, W, or combination thereof.

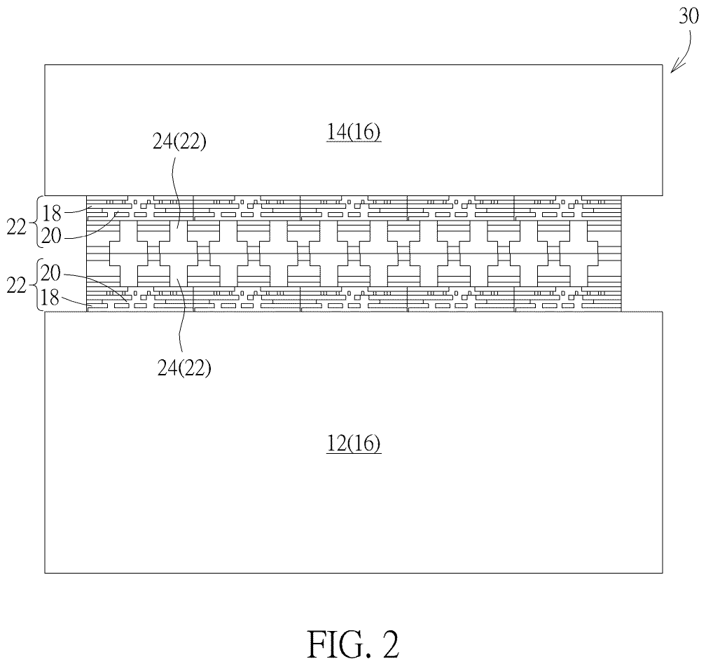

Next, as shown in FIG. 2, a hybrid bonding process is conducted by using the DBIs to connect the bottom wafer 12 and the top wafer 14 for forming a stack structure 30. Preferably, the bonding process could be accomplished by first reversing the top wafer 14 so that the front side of the top wafer 14 or the exposed surface of the DBIs 24 is facing toward the front side of the bottom wafer 12 or the exposed surface of the DBIs 24, and then performing a thermal treatment process to directly bond the two wafers 12, 14 by directly contacting the DBIs 24 on both wafers 12, 14 so that the DBIs 24 and IMD layer 18 on the top wafer 14 directly contacting the DBIs 24 and IMD layer 18 on the bottom wafer 12.

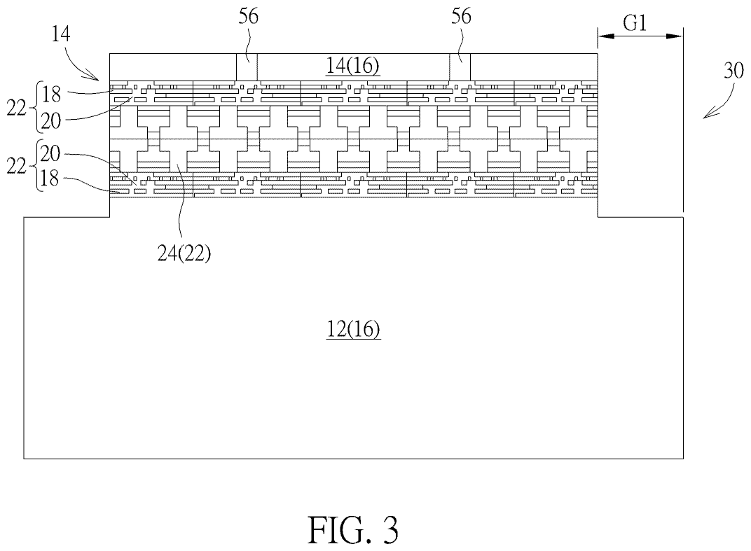

Next, as shown in FIG. 3, a planarizing process such as chemical mechanical polishing (CMP) process is conducted to remove major portion or even all of the substrate 16 of the top wafer 14 while the metal interconnect structure 22 on the substrate 16 is maintained and then an edge trimming process is conducted to remove part of the top wafer 14. Specifically, the edge trimming process could be accomplished by using a dicing or back grinding tool to remove part of the edge of the top wafer 14 so that the overall width of the remaining top wafer 14 is less than the overall width of the bottom wafer 12.

It should be noted that the edge trimming process conducted at this stage not only removes part of the edge of the top wafer 14, but could also remove part of the edge of the bottom wafer 12 after removing edges of the top wafer 14 so that top surface of the edge of the bottom wafer 12 is slightly lower than the top surface of the central portion of the bottom wafer 12 while sidewalls of the top wafer 14 are aligned with part of the sidewalls of the bottom wafer 12. In other words, after the edge trimming process is conducted, a distance or gap G1 is formed between an edge of the metal interconnect structure 22 of the top wafer 14 and an edge of the substrate 16 of the bottom wafer 12. Moreover, after most of the substrate 16 of the top wafer 14 is removed by the planarizing process, the thickness of the metal interconnect structure 22 of the remaining top wafer 14 is preferably less than 10 microns while the overall thickness of the bottom wafer 12 including both the substrate 16 and the metal interconnect structure 22 is between 700-800 microns or most preferably 750 microns. Next, an etching process is conducted on backside of top wafer 14 to form at least a trench and then depositing conductive materials into the trench for forming a TSV 56.

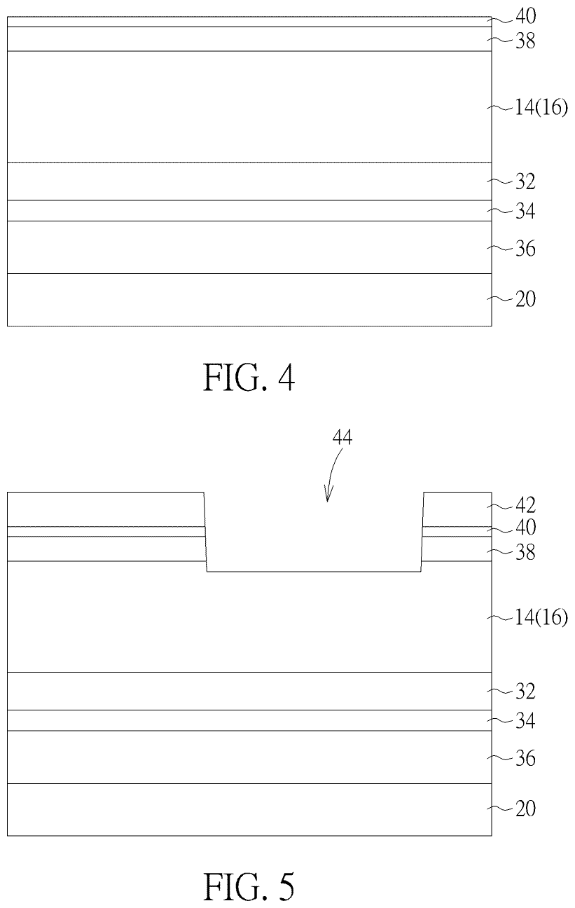

Referring to FIGS. 4-10, FIGS. 4-10 illustrate a method for fabricating a semiconductor device following FIG. 3. It should be noted that to further emphasize the details of forming metal interconnection or TSV 56 on backside of the top wafer 14, only part of the substrate 16 from the top wafer 14 and adjacent elements around the TSV 56 is shown. As shown in FIG. 4, after bonding the bottom wafer 12 and top wafer 14 through hybrid bonding to form a stack structure 30 and then using grinding tool to remove part of the substrate 16 of the top wafer 14, the remaining top wafer 14 with front side facing down and backside facing upward preferably includes a shallow trench isolation (STI) 32 made of silicon oxide disposed under the substrate 16, a contact etch stop layer (CESL) 34 made of silicon nitride (SiN) disposed under the STI 32, an ILD layer 36 disposed under the CESL 34, and a metal interconnection 20 disposed under the ILD layer 36, in which the metal interconnection 20 could essentially be the metal interconnection 20 between the substrate 16 of the top wafer 14 and the DBIs 24 as shown in FIG. 3.

Next, a first hard mask such as hard mask 38 is formed on the substrate 16 of the top wafer 14 and a second hard mask such as hard mask 40 is formed on the hard mask 38, in which the hard masks 38 and 40 are preferably made of different materials. For instance, the hard mask 38 preferably includes TEOS while the hard mask 40 includes silicon oxynitride (SiON). In this embodiment, the hard mask 38 has a thickness between 8000-10000 Angstroms or most preferably 9000 Angstroms and the thickness of the hard mask 40 is less than half the thickness of the hard mask 38. For instance, the hard mask 40 preferably has a thickness between 1800-2200 Angstroms or most preferably 2000 Angstroms.

Next, as shown in FIG. 5, a patterned mask 42 such as patterned resist is formed on the hard mask 40, and then a first stage etching process is conducted by using the patterned mask 42 as mask to remove part of the hard mask 40, part of the hard mask 38, and a small portion of the substrate 16 to form a trench 44, in which the bottom surface of the trench 44 is slightly lower than the top surface of the substrate 16.

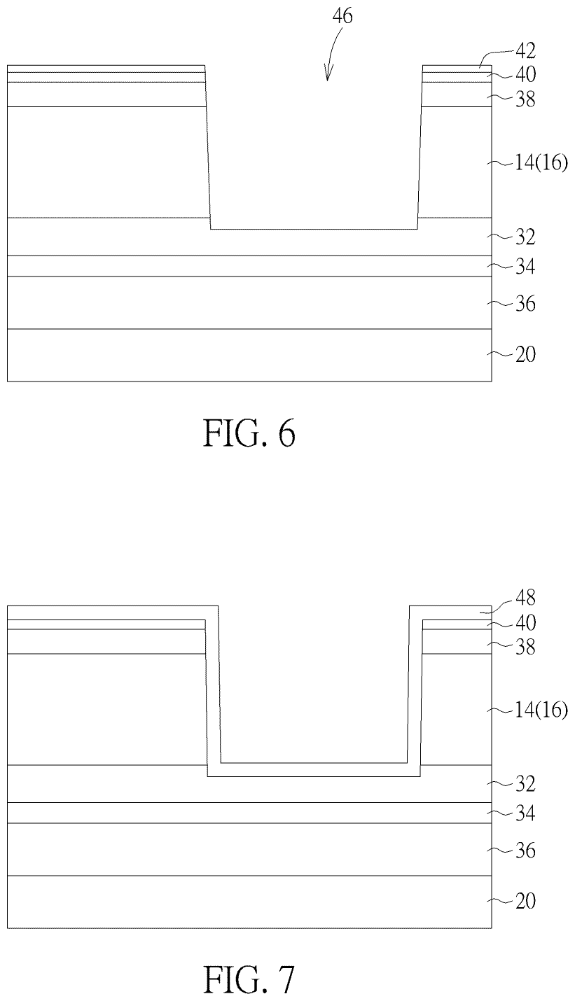

Next, as shown in FIG. 6, a second stage etching process is conducted by using the same patterned mask 42 as mask to remove part of the substrate 16 and part of the STI 32. This extends the depth of the trench 44 downward to form another trench 46, in which the bottom surface of the trench 46 could be slightly lower than the top surface of the STI 32.

Next, as shown in FIG. 7, a cleaning process could be conducted to remove the patterned mask 42 and impurities remained in the trench 46, and then an atomic layer deposition (ALD) process is conducted to form a liner 48 in the trench 46. In this embodiment, the liner 48 is preferably made of silicon oxide, but could also be made of other dielectric material such as silicon nitride. Moreover, the liner 48 is formed to cover the top surface of the hard mask 40, sidewalls of the hard mask 40, sidewalls of the hard mask 38, sidewalls of the substrate 16, and sidewalls and top surface of the STI 32.

Next, as shown in FIG. 8, a plasma etching process could be conducted without using any patterned mask to remove part of the liner 48, all of the hard mask 40, part of the STI 32 under the liner 48, part of the CESL 34, part of the ILD layer 36, and even part of the metal interconnection 20. This increases the depth of the trench 46 even more by forming another trench 50, in which the bottom surface of the trench 50 is slightly lower than the top surface of the metal interconnection 20. Specifically, the etching process conducted at this stage first removes part of the liner 48 on top surface of the hard mask 40 and on bottom surface of the trench 46 and then removes all of the hard mask 40 adjacent to two sides of the trench 46, part of the STI 32 under the trench 46, part of the CESL 34, part of the ILD layer 36, and part of the metal interconnection 20 for forming the trench 50.

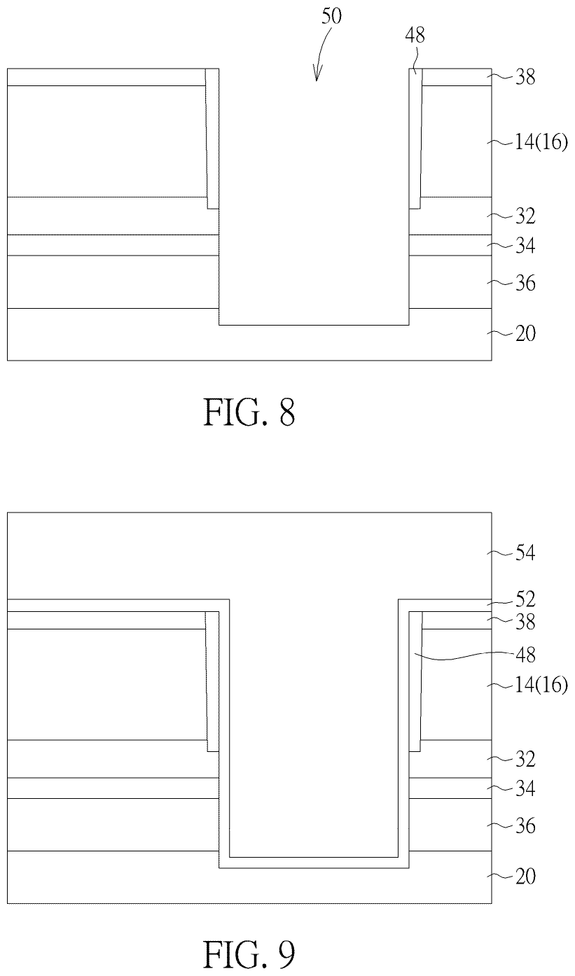

Next, as shown in FIG. 9, a barrier layer 52 is formed in the trench 50 to cover the top surface of the hard mask 38, sidewalls of the liner 48, sidewalls of the STI 32, sidewalls of the CESL 34, sidewalls of the ILD layer 36, and top surface of the metal interconnection 20, and then a metal layer 54 is formed on the barrier layer 52 to fill the trench 50 completely. In this embodiment, the barrier layer 52 could be selected from the group consisting of titanium (Ti), titanium nitride (TiN), tantalum (Ta), and tantalum nitride (TaN) and the metal layer 54 could be selected from the group consisting of tungsten (W), copper (Cu), aluminum (Al), titanium aluminide (TiAl), and cobalt tungsten phosphide (CoWP).

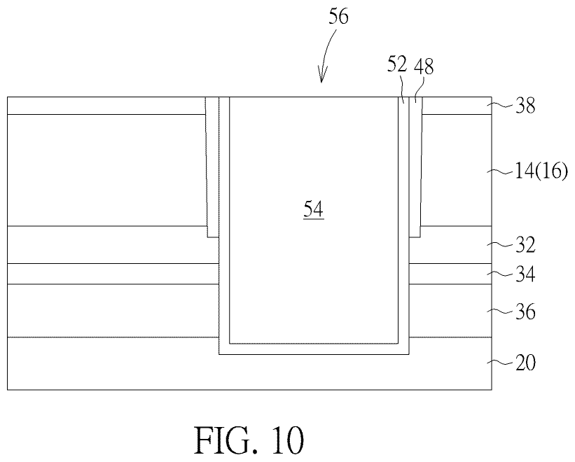

Next, as shown in FIG. 10, a planarizing process such as CMP is conducted to remove part of the metal layer 54 and part of the barrier layer 52 so that the top surface of the remaining barrier layer 52 and metal layer 54 is even with the top surface of the hard mask 38. This forms a metal interconnection of TSV 56 in the trench 50 as the TSV 56 contacts the metal interconnection 20 underneath directly.

Next, additional metal interconnect structures (not shown) could be formed on top of the TSV 56 to electrically connect the TSV 56 according to the demand of the process, and then bonding pads are formed on the metal interconnection structures. Preferably, the formation of the bonding pads could be accomplished by first forming a pad layer (not shown) on the metal interconnect structures and then a photo-etching process is conducted to remove part of the pad layer so that the remaining or patterned pad layers then become bonding pads. According to an embodiment of the present invention, the bonding pads preferably include metal and most preferably include aluminum (Al), but could also include copper (Cu), silver (Ag), gold (Au), nickel (Ni), tungsten (W), or alloy thereof. This completes the fabrication of a semiconductor device according to an embodiment of the present invention.

Referring again to FIGS. 3 and 10, FIGS. 3 and 10 further illustrate structural views of a semiconductor device according to an embodiment of the present invention. As shown in FIGS. 3 and 10, the semiconductor device includes a top wafer 14 bonded to a bottom wafer 12, in which each of the top wafer 14 and the bottom wafer 12 includes a substrate 16. The top wafer 14 further includes a hard mask 38 disposed on the substrate 16, a STI 32 disposed under the substrate 16, a CESL 34 disposed under the STI 32, an ILD layer 36 disposed under the CESL 34, a metal interconnection 20 disposed under the ILD layer 36, a metal interconnection or TSV 56 penetrating through the hard mask 38, the substrate 16, the STI 32, the CESL 34, and the ILD layer 36 to directly contact the metal interconnection 20, and a liner 48 disposed adjacent to the TSV 56.

Specifically, the top surface of the hard mask 38 is even with the top surface of the TSV 56, the top surface of the liner 48 is even with the top surface of the barrier layer 52 and metal layer 54 in the TSV 56, the bottom surfaces of the barrier layer 52 and metal layer 54 are both lower than the bottom surface of the liner 48, and the top surfaces of the CESL 34 and the ILD layer 36 are both lower than the bottom surface of the liner 48. Even though the bottom surface of the liner 48 is slightly lower than the top surface of the STI 32 in this embodiment, according to other embodiment of the present invention, it would also be desirable to adjust the depth of the trench 48 during formation of the liner 48 in FIGS. 6-7 so that the bottom surface of the liner 48 could be higher than, even with, or lower than the top surface of the STI 32, higher than, even with, or lower than the top surface of the CESL 34, or higher than, even with, or lower than the top surface of the ILD layer 36 but still higher than the bottom surface of the TSV 56 in all occasions, which are all within the scope of the present invention.

Overall, the present invention proposes an approach of forming TSVs on backside of the top wafer, which first bonds a top wafer to a bottom wafer to form a stack structure and then conducts an edge trimming process to remove part of the top wafer as the trimmed top wafer includes a STI 32 disposed under the substrate 16, a CESL 34 disposed under the STI 32, an ILD layer 36 disposed under the CESL 34, and metal interconnection 20 disposed under the ILD layer 36. Next, multiple stage of etching processes were conducted to remove part of the substrate, part of the CESL, and part of the ILD layer to form deeper trench and then conductive materials are deposited into the trench to form a TSV.

According to a preferred embodiment of the present invention, the utilization of the above processes for forming TSVs on backside of the top wafer has following advantages. First, it would be desirable to obtain lower resistance for copper wires after the wafer or dies are bonded face to face. Next, fabrication processes could be carried out directly on bulk silicon instead of silicon-on-insulator (SOI) substrate as the fabrication processes could be conducted directly within fab instead of outsourcing to other outsourced semiconductor assembly and test (OSAT) facilities. Moreover, thinner silicon substrate used during front end of the process is substantially more effective in alignment than conventional TSV-via-middle approach, which further improves quality and yield of die production.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
providing a stack structure comprising:
a shallow trench isolation (STI) under a first substrate;
a contact etch stop layer (CESL) under the STI;
an interlayer dielectric (ILD) layer under the CESL; and
a first metal interconnection under the ILD layer; and
forming a second metal interconnection penetrating through the first substrate, the STI, the CESL, and the ILD layer to contact the first metal interconnection and a liner adjacent to a sidewall of the second metal interconnection.

2. The method of claim 1, further comprising:
bonding the first substrate to a second substrate, wherein the first substrate faces downward and the second substrate faces upward;
performing a trimming process to trim an edge of the first substrate;
forming a first trench in the first substrate; and
forming a metal layer in the first trench to form the second metal interconnection.

3. The method of claim 2, further comprising:
forming a first hard mask on the first substrate;
forming a second hard mask on the first hard mask;
removing the second hard mask, the first hard mask, the first substrate, and the STI to form a second trench;
forming the liner in the second trench;
removing the liner, the CESL, and the ILD layer to form the first trench exposing the first metal interconnection;
forming a barrier layer in the second trench;
forming the metal layer in the second trench; and
planarizing the barrier layer and the metal layer to form the second metal interconnection.

4. The method of claim 3, wherein the first hard mask and the second hard mask comprise different materials.

5. The method of claim 3, wherein top surfaces of the liner and the barrier layer are coplanar.

6. The method of claim 3, wherein a bottom surface of the barrier layer is lower than a bottom surface of the liner.

7. The method of claim 1, wherein a top surface of the CESL is lower than a bottom surface of the liner.

8. A semiconductor device, comprising:
a shallow trench isolation (STI) under a first substrate;
a contact etch stop layer (CESL) under the STI;
an interlayer dielectric (ILD) layer under the CESL;
a first metal interconnection under the ILD layer;
a second metal interconnection penetrating through the first substrate, the STI, the CESL, and the ILD layer to contact the first metal interconnection; and
a liner adjacent to a sidewall of the second metal interconnection.

9. The semiconductor device of claim 8, wherein the first substrate is bonded to a second substrate.

10. The semiconductor device of claim 8, further comprising a hard mask on the first substrate.

11. The semiconductor device of claim 10, wherein top surfaces of the hard mask and the second metal interconnection are coplanar.

12. The semiconductor device of claim 8, wherein the second metal interconnection comprises:
a barrier layer; and
a metal layer on the barrier layer.

13. The semiconductor device of claim 12, wherein top surfaces of the liner and the barrier layer are coplanar.

14. The semiconductor device of claim 12, wherein a bottom surface of the barrier layer is lower than a bottom surface of the liner.

15. The semiconductor device of claim 8, wherein a top surface of the CESL is lower than a bottom surface of the liner.
